(19) United States
(12) Patent Application Publication
(10) Pub. No.: US 2022/0400581 A1
(43) Pub. Date: Dec. 15, 2022

(54) PORTABLE ELECTRONIC DEVICE

(71) Applicant: Acer Incorporated, New Taipei City (TW)

(72) Inventors: Chun-Chieh Wang, New Taipei City (TW); Wen-Neng Liao, New Taipei City (TW); Cheng-Wen Hsieh, New Taipei City (TW); Tsung-Ting Chen, New Taipei City (TW)

(73) Assignee: Acer Incorporated, New Taipei City (TW)

(21) Appl. No.: 17/832,705

(22) Filed: Jun. 6, 2022

(30) Foreign Application Priority Data
Jun. 9, 2021 (TW) 110121049

(51) Int. Cl. H05K 7/20; H05K 7/16; G06F 1/20; G06F 1/16

(52) U.S. Cl. CPC H05K 7/20336; H05K 7/16; H05K 7/20436; G06F 1/203; G06F 1/1681; G06F 1/1616

(57) ABSTRACT

A portable electronic device including a first body, a second body, a heat source, a first heat pipe, a second heat pipe, and a heat conducting element is provided. The second body is pivotally connected to the first body. The heat source is disposed in the first body and thermally coupled to the heat source. The second heat pipe is disposed in the first body and thermally coupled to the first heat pipe. The heat conducting element is connected to and thermally coupled to the second body, and the heat conducting element slidably contacts the second heat pipe and is thermally coupled to the second heat pipe.

### CROSS-REFERENCE TO RELATED APPLICATION

This application claims the priority benefit of Taiwan application serial no. 110121049, filed on Jun. 9, 2021. The entirety of the above-mentioned patent application is hereby incorporated by reference herein and made a part of this specification.

### BACKGROUND

### Technical Field

The disclosure relates to an electronic device, and in particular to a portable electronic device.

### Description of Related Art

With an increasingly larger volume of data computation, a laptop generates a lot of heat during operation. In a current heat-dissipation design, one or more heat pipes and fans are disposed inside a host to discharge the heat generated by heat sources including a central processor unit, a graphics processor, and other electronic elements from the host. Specifically, the heat pipe conducts the heat generated by the aforementioned heat sources to where the fan is, so that air flow generated by the fan is used for heat exchange, and hot air is thus discharged outward. Generally speaking, the back side of most hosts is equipped with a heat-dissipation opening as a heat-dissipation path to discharge the hot air, but the heat-dissipation efficiency may not be good as the heat-dissipation path can be easily blocked by external objects.

### SUMMARY

The disclosure provides a portable electronic device, which has good heat-dissipation efficiency.

The disclosure proposes a portable electronic device which includes a first body, a second body, a heat source, a first heat pipe, a second heat pipe, and a heat conducting element. The second body is pivotally connected to the first body. The heat source is disposed in the first body. The first heat pipe is disposed in the first body and is thermally coupled to the heat source. The second heat pipe is disposed in the first body and is thermally coupled to the first heat pipe. The heat conducting element is connected to and thermally coupled to the second body. The heat conducting element slidably contacts the second heat pipe and is thermally coupled to the second heat pipe.

Based on the above, in a portable electronic device of the disclosure, heat generated by the heat source is conducted to the heat conducting element via the first heat pipe and the second heat pipe, and conducted to the second body via the heat conducting element. Since the second body has a larger heat exchange area, the heat conducted to the second body is exchanged with the outside to speed up the heat-dissipation rate and avoid a work performance decline due to heat being accumulated inside the first body.

To further describe the above features and advantages of the disclosure, embodiments accompanied with drawings are described below in details.

### BRIEF DESCRIPTION OF THE DRAWINGS

FIG. 1 is a schematic view of a portable electronic device according to an embodiment of the disclosure.

FIG. 2 is an enlarged schematic view of a portion of the portable electronic device of FIG. 1.

FIG. 3 is a schematic view of a portable electronic device according to another embodiment of the disclosure.

FIG. 4 is an enlarged schematic view of a portion of the portable electronic device of FIG. 3.

FIG. 5 is a schematic view of a portable electronic device according to another embodiment of the disclosure.

FIGS. 6 and 7 are respectively enlarged schematic views of a portion of the portable electronic device of FIG. 5.

FIG. 8 is a schematic view of a portable electronic device according to another embodiment of the disclosure.

### DESCRIPTION OF THE EMBODIMENTS

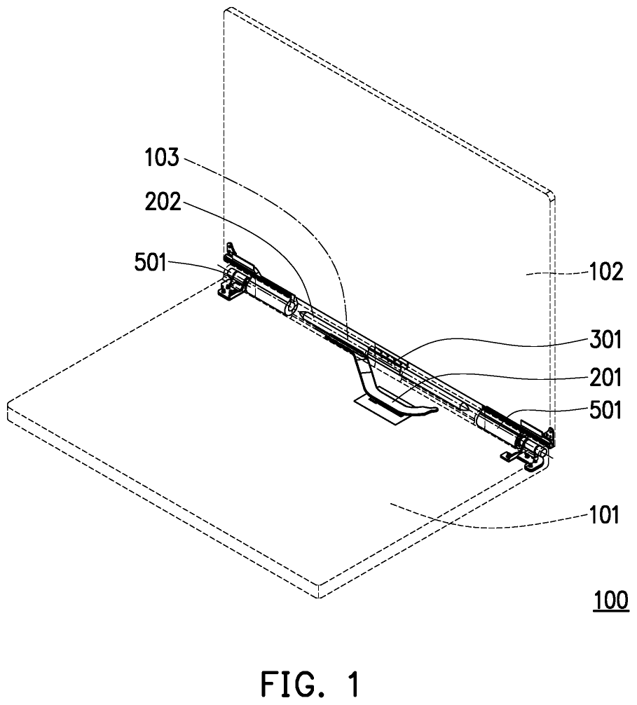

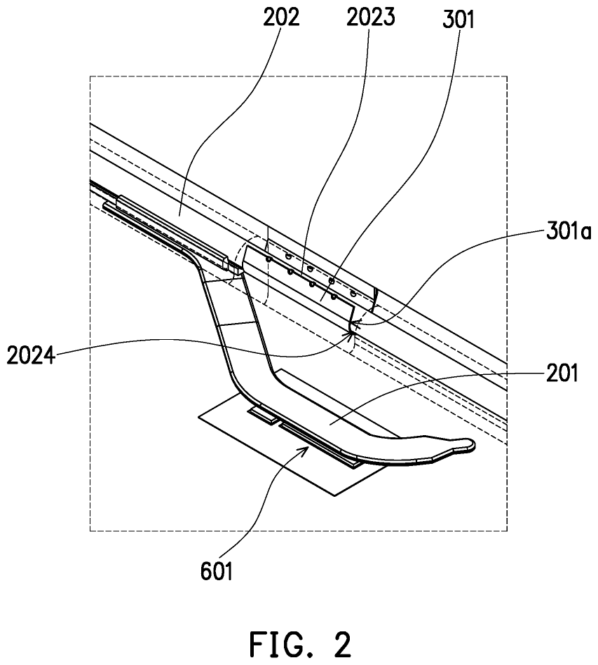

FIG. 1 is a schematic view of a portable electronic device according to an embodiment of the disclosure. FIG. 2 is an enlarged schematic view of a portion of the portable electronic device of FIG. 1. It is to be noted that a first body 101 and a second body 102 in the drawings are drawn with dashed lines to facilitate the presentation of the disposition of the internal structure. Referring to FIGS. 1 and 2, in this embodiment, a portable electronic device 100 may be a laptop, and includes the computing first body 101, the second body 102, a heat source 601, a first heat pipe 201, a second heat pipe 202, and a heat conducting element 301. The first body 101 may be a host with a logical operation function, and the second body 102 may be a display. The second body 102 is pivotally connected to the first body 101 to rotate relative to the first body 101. The second body 102 is electrically connected to the first body 101 to transmit signals or electricity.

The heat source 601, the first heat pipe 201, and the second heat pipe 202 are disposed in first body 101. The heat source 601 may be a central processor unit, a graphics processor, or other electronic elements, and the first heat pipe 201 is thermally coupled to the heat source 601. On the other hand, the second heat pipe 202 is located on the pivot side of the first body 101. The first heat pipe 201 extends from the heat source 601 towards the second heat pipe 202, and is thermally coupled to the second heat pipe 202. The first heat pipe 201 is used to conduct heat generated by the heat source 601 outward and then conduct the heat to the second heat pipe 202.

The heat conducting element 301 may be made of a high thermal conductivity material, and may be integrally formed on the pivot side of the second body 102, riveted to the pivot side of the second body 102, engaged with the pivot side of the second body 102, locked to the pivot side of the second body 102, welded to the pivot side of the second body 102, or glued to the pivot side of the second body 102. Furthermore, the heat conducting element 301 is thermally coupled to the second body 102 and the second heat pipe 202, and the heat conducted to the second heat pipe 202 may be conducted to the second body 102 via the heat conducting element 301. Since the second body 102 has a larger heat exchange area, the heat conducted to the second body 102 may be exchanged with the outside to speed up the heat-dissipation rate and avoid a work performance decline due to the heat being accumulated inside the first body 101.

Still referring to FIGS. 1 and 2, in this embodiment, the heat conducting element 301 may rotate relative to the first body 101 along with the second body 102. The heat conducting element 301 may slidably contact the second heat pipe 202, and the heat conducting element 301 is in surface contact with the second heat pipe 202, so the heat conducting element 301 has a larger heat conduction area. For example, the heat conducting element 301 may be a U-shaped plate made of a high thermal conductivity material, and encapsulate the second heat pipe 202.

On the other hand, the second heat pipe 202 may be a cylindrical heat pipe, or in other words, a section (that is, an intermediate section 2023) encapsulated by the heat conducting element 301 in the second heat pipe 202 is a cylindrical section to improve the smoothness of rotation of the second body 102 relative to the first body 101. Furthermore, the heat conducting element 301 has a concave arc surface 301a to contact and encapsulate an outer wall surface 2024 of the intermediate section 2023 of the second heat pipe 202.

In this embodiment, the portable electronic device 100 further includes a hinge 501. The second body 102 is pivotally connected to the first body 101 through the hinge 501, and the second body 102 rotates relative to the first body 101 about a rotation axis 103. Specifically, the rotation axis 103 extends through the second heat pipe 202, and the second heat pipe 202 is coaxial with the rotation axis 103. When the second body 102 rotates relative to the first body 101, the heat conducting element 301 rotates relative to the second heat pipe 202 about the rotation axis 103. The heat conducting element 301 and the second heat pipe 202 work together to stabilize the rotation of the second body 102 relative to the first body 101.

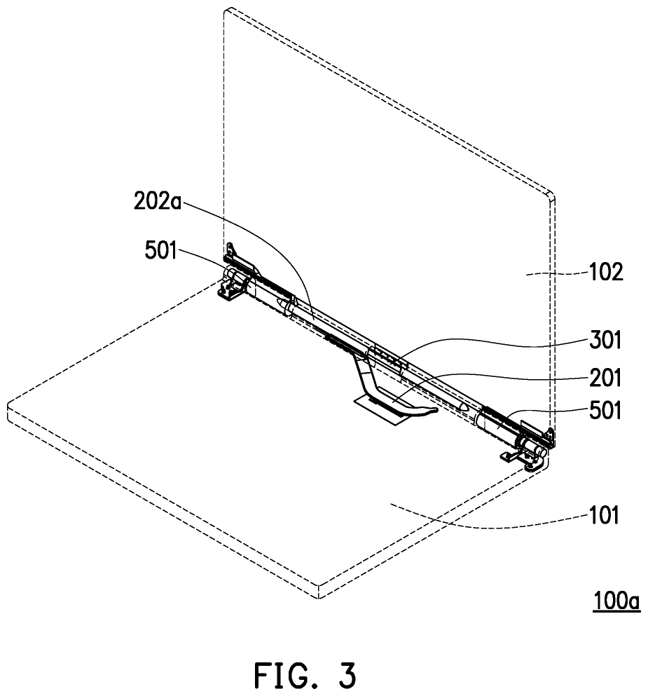

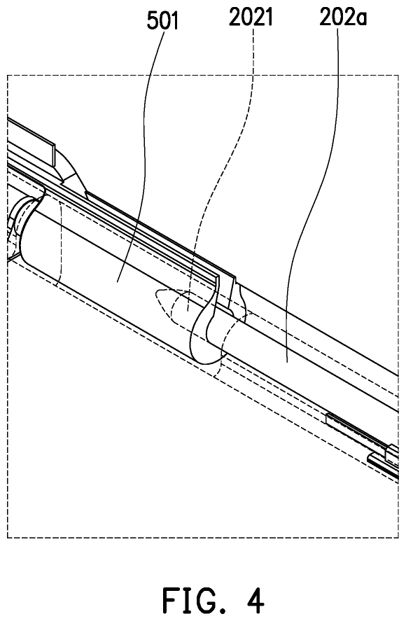

FIG. 3 is a schematic view of a portable electronic device according to another embodiment of the disclosure. FIG. 4 is an enlarged schematic view of a portion of the portable electronic device of FIG. 3. It is to be noted that the first body 101 and the second body 102 in the drawings are drawn with dashed lines to facilitate the presentation of the disposition of the internal structure. Referring to FIGS. 3 and 4, compared with the portable electronic device 100 of the previous embodiment, in a portable electronic device 100a of this embodiment, a first terminal 2021 of a second heat pipe 202a relative to the intermediate section 2023 is inserted into the hinge 501, and the rotation of the second body 102 relative to the first body 101 is thus stabilized.

The hinge 501 may be made of a thermal conductivity material, and the first terminal 2021 of the second heat pipe 202a is thermally coupled to the hinge 501. Therefore, the heat conducted to the second heat pipe 202a may be conducted to the second body 102 via the hinge 501, thereby providing multiple heat-dissipation paths.

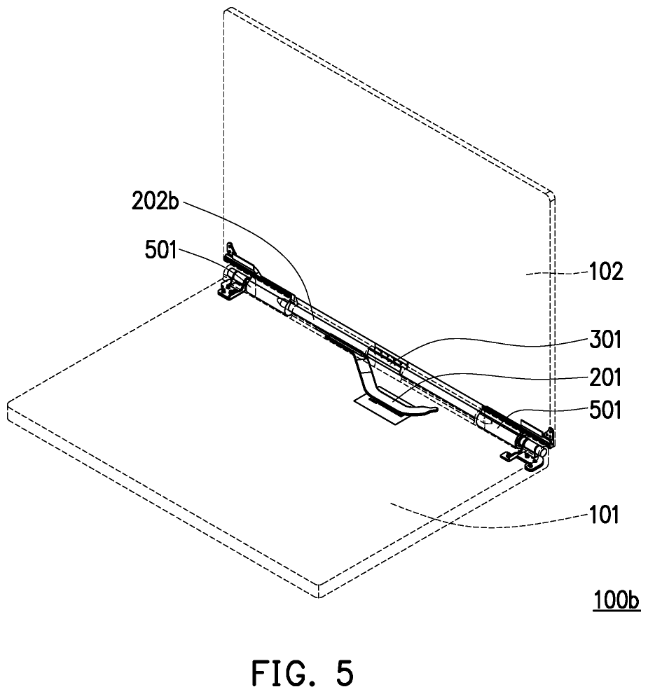

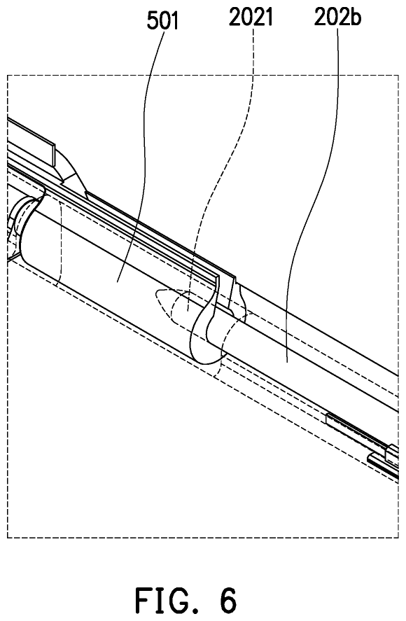

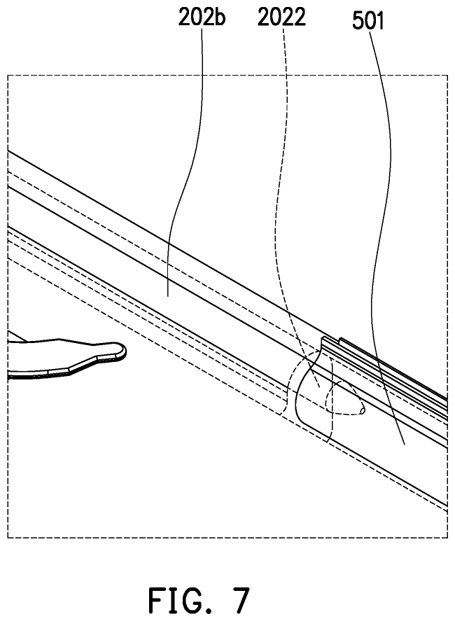

FIG. 5 is a schematic view of a portable electronic device according to another embodiment of the disclosure. FIGS. 6 and 7 are respectively enlarged schematic views of a portion of the portable electronic device of FIG. 5. It is to be noted that the first body 101 and the second body 102 in the drawings are drawn with dashed lines to facilitate the presentation of the disposition of the internal structure. Referring to FIGS. 5 to 7, compared with the portable electronic device 100 of the previous embodiment, in a portable electronic device 100b of this embodiment, the first terminal 2021 and a second terminal 2022 of a second heat pipe 202b relative to the intermediate section 2023 is inserted into the hinge 501, and the rotation of the second body 102 relative to the first body 101 is thus stabilized.

The hinge 501 may be made of a thermal conductivity material, and the first terminal 2021 and the second terminal 2022 of the second heat pipe 202b are thermally coupled to the hinge 501. Therefore, the heat conducted to the second heat pipe 202b may be conducted to the second body 102 via the hinge 501, thereby providing multiple heat-dissipation paths. It should be noted that the intermediate section 2023 is located between the first terminal 2021 and the second terminal 2022.

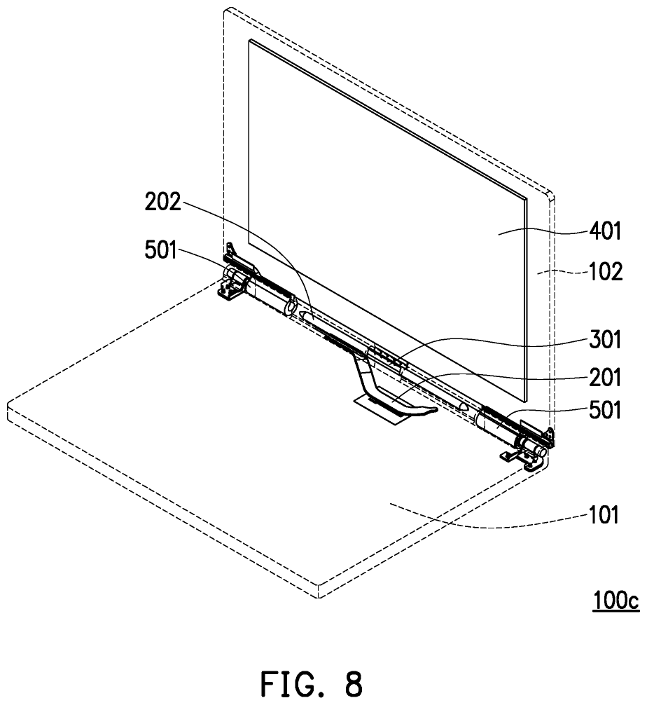

FIG. 8 is a schematic view of a portable electronic device according to another embodiment of the disclosure. It is to be noted that the first body 101 and the second body 102 in the drawings are drawn with dashed lines to facilitate the presentation of the disposition of the internal structure. Referring to FIG. 8, compared with the portable electronic device 100 of the previous embodiment, a portable electronic device 100c of this embodiment further includes a vapor chamber 401. The vapor chamber 401 is disposed in the second body 102, and the vapor chamber 401 may be directly or indirectly thermally coupled to the heat conducting element 301. Therefore, the heat conducted from the heat conducting element 301 to the second body 102 may be quickly conducted and diffused by the vapor chamber 401.

In particular, the disposition method of the second heat pipe 202a shown in FIGS. 3 and 4 may be integrated to the portable electronic device 100c. In addition, the disposition method of the second heat pipe 202a shown in FIGS. 5 to 7 may be integrated to the portable electronic device 100c, too.

In summary, in the portable electronic device of the disclosure, heat generated by the heat source may be conducted to the heat conducting element via the first heat pipe and the second heat pipe, and conducted to the second body via the heat conducting element. Since the second body has a larger heat exchange area, the heat conducted to the second body may be exchanged with the outside to speed up the heat-dissipation rate and avoid a work performance decline due to heat being accumulated inside the first body. In some embodiments, a vapor chamber is disposed inside the second body so that heat conducted to the second body is quickly conducted and diffused.

Although the disclosure has been disclosed in the above by way of embodiments, the embodiments are not intended to limit the disclosure. Those with ordinary knowledge in the technical field can make various changes and modifications without departing from the spirit and scope of the disclosure. Therefore, the protection scope of the disclosure is subject to the scope of the appended claims.

What is claimed is:

1. A portable electronic device, comprising:
a first body;
a second body, pivotally connected to the first body;
a heat source, disposed in the first body;
a first heat pipe, disposed in the first body, thermally coupled to the heat source;
a second heat pipe, disposed in the first body, thermally coupled to the first heat pipe; and
a heat conducting element, connected to and thermally coupled to the second body, wherein the heat conducting element slidably contacts the second heat pipe and is thermally coupled to the second heat pipe.

2. The portable electronic device according to claim 1, wherein the heat conducting element encapsulates the second heat pipe.

3. The portable electronic device according to claim 1, wherein the second heat pipe is a cylindrical heat pipe, the heat conducting element has a concave arc surface, and the concave arc surface contacts an outer wall surface of the cylindrical heat pipe.

4. The portable electronic device according to claim 1, further comprising a hinge, wherein the second body is pivotally connected to the first body through the hinge, the second body rotates relative to the first body about a rotation axis, and the second heat pipe is coaxial with the rotation axis.

5. The portable electronic device according to claim 4, wherein the second heat pipe comprises a first terminal, a second terminal relative to the first terminal, and an intermediate section between the first terminal and the second terminal, the heat conducting element slidably contacts the intermediate section, and at least one of the first terminal and the second terminal is inserted into the hinge.

6. A portable electronic device, comprising:
a first body;
a second body, pivotally connected to the first body;
a heat source, disposed in the first body;
a first heat pipe, disposed in the first body, thermally coupled to the heat source;
a second heat pipe, disposed in the first body, thermally coupled to the first heat pipe;
a heat conducting element, connected to and thermally coupled to the second body, wherein the heat conducting element slidably contacts the second heat pipe and is thermally coupled to the second heat pipe; and
a vapor chamber, disposed in the second body.

7. The portable electronic device according to claim 6, wherein the heat conducting element encapsulates the second heat pipe.

8. The portable electronic device according to claim 6, wherein the second heat pipe is a cylindrical heat pipe, the heat conducting element has a concave arc surface, and the concave arc surface contacts an outer wall surface of the cylindrical heat pipe.

9. The portable electronic device according to claim 6, further comprising a hinge, wherein the second body is pivotally connected to the first body through the hinge, the second body rotates relative to the first body about a rotation axis, and the second heat pipe is coaxial with the rotation axis.

10. The portable electronic device according to claim 9, wherein the second heat pipe comprises a first terminal, a second terminal relative to the first terminal, and an intermediate section between the first terminal and the second terminal, the heat conducting element slidably contacts the intermediate section, and at least one of the first terminal and the second terminal is inserted into the hinge.
